(19) United States
(12) Patent Application Publication
(10) Pub. No.: US 2007/0163756 A1
(43) Pub. Date: Jul. 19, 2007

(54) Closed-loop latent heat cooling method and capillary force or non-nozzle module thereof

(75) Inventors: Chih-Yao Wang, Hsinchu (TW); Chiung-I Lee, Hsinchu (TW); Heng-Chieh Chien, Hsichu (TW); Shu-Jung Yang, Hsinchu (TW); Ra-Min Tain, Hsinchu (TW); Chih-Min Hsiung, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/592,293

(22) Filed: Nov. 3, 2006

(30) Foreign Application Priority Data
Jan. 13, 2006 (TW) 095101487

(51) Int. Cl. H05K 7/20

(52) U.S. Cl. 165/104.26; 165/104.33; 361/700

(57) ABSTRACT

A closed-loop latent heat cooling method and a capillary force or non-nozzle module thereof are provided, wherein a cooling fluid in a storage tank flows to a gasification pipe via a liquid pipe; the gasification pipe connects with a capillary force or non-nozzle structure; the cooling fluid keeps a liquid thin film in the gasification pipe, and after absorbing the heat of electronic components, it keeps a thin film in a boiling state; then, it is gasified and rises to a vapor chamber more efficiently; the gasified cooling fluid in the vapor chamber flows to a condenser via a vapor pipe and flows back to the storage tank via the liquid pipe after condensed to be a liquid in the condenser.

### CROSS-REFERENCE TO RELATED APPLICATIONS

This non-provisional application claims priority under 35 U.S.C. § 119(a) on Patent Application No(s). 095101487 filed in Taiwan, R.O.C. on Jan. 13, 2006, the entire contents of which are hereby incorporated by reference.

### BACKGROUND OF THE INVENTION

1. Field of Invention

The present invention relates to a heat cooling method for an electronic component, and more particularly, to a closed-loop latent heat cooling method and a capillary force or non-nozzle module using the same.

2. Related Art

As for the technology of relieving heat from an electronic component by transferring latent heat during the gas-liquid two-phase change, a two-phase thermosyphon heat cooling technology has already been developed with the following working principle. A cooling fluid is heated and gasified in a vaporizer contacting with a heat source, to relieve a lot of heat from the heat source; and then the subsequently formed gas pushes the heated liquid and gas into a condenser to exchange heat. After passing through the condenser, the condensed cooling fluid flows back into the vaporizer to exchange heat by means of gravity or external pump pressure, so as to form a circulation, such as U.S. Pat. No. 4,393,663.

A heat sink designed through such principle can be brought into practical use; however, the heat cooling efficiency and heat cooling wattage are limited by the amount of cooling fluid in the vaporizer. When there is less cooling fluid, it may dry up due to rapid gasification in the case of high calorific wattage, while the gas formed after the gasification does not have sufficient time to be condensed into liquid and flow back to the vaporizer in time to exchange heat, thus the electronic component is burnt and damaged due to over heat. If there is too much cooling fluid, a thicker liquid film, or even a pool is formed on the vaporizer. At this point, the heat transferred from the heat source to the vapor chamber will cause a pool-boiling phenomenon of the cooling fluid. Therefore, the efficiency of heat exchange is poor during the pool-boiling period, thereby degrading the heat cooling efficiency of the whole system.

Furthermore, through the technology of relieving the heat of an electronic component by transferring latent heat during the gas-liquid two-phase change, an ink-jet heat cooling technology has also been developed, which is a kind of nuclear-boiling heat cooling mode. The heat resistance value for nuclear boiling is relatively small during the vaporization of the cooling fluid, i.e., the vaporization of the cooling fluid requires less heat and shorter time. Ink-jet heat cooling technology is driven by the following methods, all of which achieve the purpose of heat cooling by means of nozzles or ink-jets.

1. An ink-jet cooling mechanism is formed by mixing air with the cooling fluid in the nozzle and then ejecting them out, such as in U.S. Pat. No. 4,068,495, U.S. Pat. No. 4,141,224, and U.S. Pat. No. 4,711,431.

2. The cooling fluid is atomized through an atomizer, and the generated droplets are sprayed onto the surface of the heat source, so as to achieve a spray cooling effect, such as in U.S. Pat. No. 5,220,804, U.S. Pat. No. 5,854,092, U.S. Pat. No. 5,992,159, U.S. Pat. No. 5,999,404, U.S. Pat. No. 6,108,201, U.S. Pat. No. 6,498,725 B2, U.S. Pat. No. 6,836,131 B2, and U.S. Pat. No. 6,889,515 B2.

3. The droplets for spraying are generated by a pressing or heating mechanism in an ink-jet type similar to an ink cartridge of a printer, such as in U.S. Pat. No. 6,205,799 B1, U.S. Pat. No. 6,349,554 B2, U.S. Pat. No. 6,457,321 B1, U.S. Pat. No. 6,550,263 B2, and U.S. Pat. No. 6,646,879 B2.

In the aforementioned patents, the cooling fluid reaches the surface of the heat source mainly through various designs of nozzles and ink-jets, and heat cooling is achieved by the cooling fluid through transferring latent heat. However, these designs including nozzles and inkjet must be improved in some aspects. For example, due to the influence of a gas flow generated by the vaporization of the cooling fluid, cooling fluid droplets of excessively small size or excessively low speed cannot penetrate the gas area and reach the surface of the heat source for heat dissipation. Additionally, cooling fluid droplets of excessively large size or excessively high speed easily penetrate the gas area and reach the surface of the heat source, but a thicker liquid film may be formed, resulting in the pool-boiling phenomenon. Thus, the heat resistance value for vaporization of the cooling fluid is much larger than that of nuclear boiling, so heat-cooling efficiency is reduced. Therefore, control of the amount of cooling fluid becomes a key point.

### SUMMARY OF THE INVENTION

According to one aspect of the present invention, a closed-loop latent heat cooling method is provided, wherein the heat of the electronic component is relieved through transferring latent heat during the gas-liquid two-phase change. The method includes the following steps. Cooling fluid in a storage tank flows to a gasification pipe via a liquid pipe, wherein two side surfaces of the gasification pipe are connected with an electronic component and a vapor chamber respectively. After absorbing heat generated from the electronic component, the cooling fluid in the gasification pipe is kept in a film boiling state, and rises to the vapor chamber after being gasified. After that, the gasified cooling fluid in the vapor chamber flows to a condenser via a vapor pipe. Then, heat exchange is performed in the condenser to condense the gasified cooling fluid back to liquid. And finally, the liquid flows back to the storage tank from the condenser via the liquid pipe.

According to another aspect of the present invention, a closed-loop latent heat cooling module is provided, which includes a cooling fluid, a storage tank, a vapor chamber, a condenser, and a loop pipe. The cooling fluid is used to absorb the heat of the electronic component. The storage tank is used to store the cooling fluid. The vapor chamber is a space for accommodating the gas generated by the cooling fluid being boiling and vaporized after absorbing the heat of the electronic component. The condenser is used to condense the gasified cooling fluid into liquid. The loop pipe is used to connect the storage tank, the vapor chamber, and the condenser into a closed loop. The loop pipe comprises a liquid pipe, a vapor pipe, and a gasification pipe, wherein the liquid pipe connects the storage tank and the condenser, and serves as the pipe for the back flow of the storage tank itself; the vapor pipe connects the vapor chamber and the condenser; and the gasification pipe connects between the liquid pipes of the back flow of the storage tank itself, with both side surfaces connecting with the electronic component and the vapor chamber respectively. The gasification pipe has the microstructure with capillary force or a non-nozzle structure, such that a liquid film kept in the film boiling state is formed in the gasification pipe.

The features and practice of the preferred embodiments of the present invention will be illustrated below in detail with reference to the drawings.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and which thus is not limitative of the present invention, and wherein:

FIG. 1 is a schematic view of a closed-loop latent heat cooling method and the module thereof in one preferred embodiment of the present invention;

FIG. 2 is a schematic view of maintaining the liquid film through the principle of communicating pipe for the closed-loop latent heat cooling method and the module thereof according to one preferred embodiment of the present invention;

FIG. 3 is a schematic view of maintaining the liquid film through the combination of a capillary phenomenon and externally applied pressure for the closed-loop latent heat cooling method and the module thereof according to one preferred embodiment of the present invention;

FIG. 4 is a schematic view of maintaining the liquid film through the combination of the waterfall and externally applied pressure principles for the closed-loop latent heat cooling method and the module thereof according to one preferred embodiment of the present invention; and

FIG. 5 is a schematic view of using the cooling fluid with a high boiling temperature through using an external cooling chip for the closed-loop latent heat cooling method and the module thereof according to one preferred embodiment of the present invention.

### DETAILED DESCRIPTION OF THE INVENTION

The contents of the present invention are described in details through specific embodiments with reference to the figures. The reference numerals mentioned in the specification correspond to equivalent reference numerals in the figures.

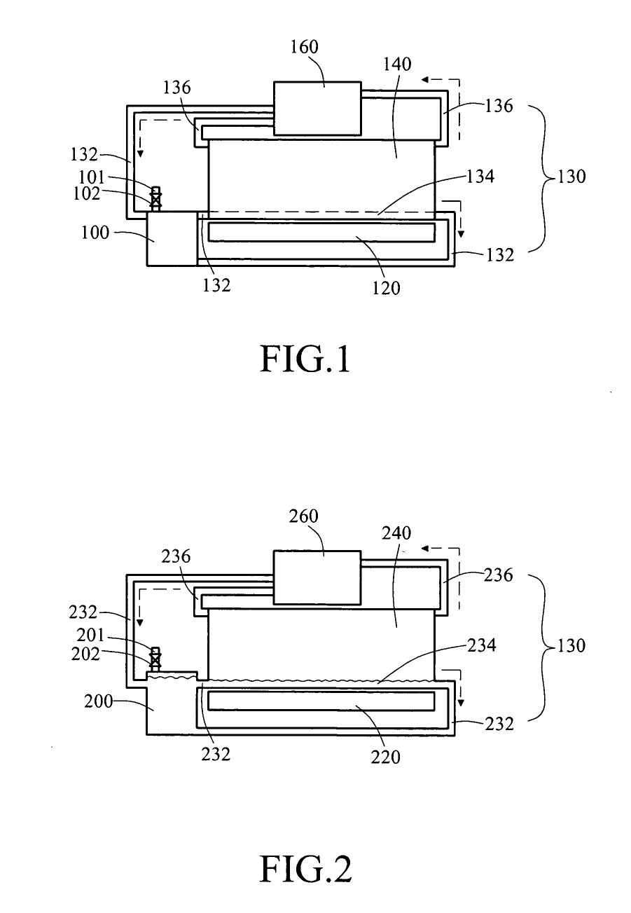

FIGS. 1 to 5 are schematic views of the closed-loop latent heat cooling method and the module thereof according to preferred embodiments of the present invention. A number of gasification pipes may be disposed above an electronic component to accelerate the heat dissipation, or a number of liquid pipes and vapor pipes may be equipped depending on requirements. However, in order to illustrate briefly and clearly, FIGS. 1 to 5 are the schematic views of the closed-loop latent heat cooling method and the method therefor with liquid pipes, vapor pipes, and gasification pipes only sufficient to illustrate the embodiments.

FIG. 1 is a schematic view of the closed-loop latent heat cooling method and the module thereof in one preferred embodiment of the present invention. As shown in FIG. 1, the embodiment includes: a storage tank 100 for storing a cooling fluid, wherein the cooling fluid is used to absorb the heat of an electronic component 120; a vapor chamber 140, which is a region for accommodating the gas generated by the cooling fluid being boiling and vaporized after absorbing the heat of the electronic component 120; a condenser 160 for condensing the gasified cooling fluid into liquid; and a loop pipe 130 for connecting the storage tank 100, the vapor chamber 140, and the condenser 160 into a closed loop. According to the state of the cooling fluid therein, the loop pipe 130 is classified into the liquid pipe 132, the vapor pipe 136, and the gasification pipe 134, wherein the liquid pipe 132 connects the storage tank 100 and the gasification pipe 134, connects the storage tank 100 and the condenser 160, and serves as the pipe for the back flow of the storage tank 100 itself; the vapor pipe 136 connects the vapor chamber 140 and the condenser 160; and the gasification pipe 134 connects between the liquid pipes 132 of the back flow of the storage tank 100 itself, with the two side surfaces being connected with the electronic component 120 and the vapor chamber 140 respectively, and the gasification pipe 134 has a liquid film always kept in a film boiling state.

Each of the loop pipe 130, the storage tank 100, the vapor chamber 140, and the condenser 160 is formed, for example, by integrating or bonding, and they are also combined with one another by integrating or bonding. The integrating method is, for example, forging, punching, or computerized numberized control (CNC), and the bonding method is, for example, sintering or installing at least one fastener.

In FIG. 1, a check valve 102 is closed after the cooling fluid has already been filled through a filler pipe 101. The cooling fluid within the storage tank 100 flows to the gasification pipe 134 through the liquid pipe 132, wherein the electronic component 120 and the vapor chamber 140 are connected with the two side surfaces of the gasification pipe 134 respectively. The cooling fluid in the gasification pipe 134 becomes the liquid film kept in a film boiling state after absorbing the heat of the electronic component 120, and meanwhile, it is gasified and rises to the vapor chamber 140. The cooling fluid condensed at the end of the gasification pipe 134 flows back to the storage tank 100 through the liquid pipe 132. The cooling fluid gasified in the vapor chamber 140 flows to the condenser 160 through the vapor pipe 136, and is condensed into liquid in the condenser 160. Then, the cooling fluid in a liquid state flows back to the storage tank 100 from the condenser 160 through the liquid pipe 132.

The cooling fluid is, for example, water, refrigerant, liquid nitrogen, or another suitable fluid. The cooling fluid further includes at least one additive to increase the required characteristics of the cooling fluid, wherein the additive is, for example, an antifreezing agent.

The material of the gasification pipe 134 is, for example, high heat-conductive material, wherein the side surface of the gasification pipe 134 is connected with the vapor chamber, for example, through an open connection, i.e., suitable for gasifying and raising the cooling fluid in the gasification pipe 134 to the vapor chamber 140. The side surface of the vapor chamber 140 connected to the gasification 134 is not a physical tube wall. The side surface of the gasification pipe 134 is connected with the vapor chamber 140 only at the position where the gasification pipe 134 enters into the vapor chamber 140, and is supported by half of the gasification pipe 134 connected with the electronic component 120.

The aforementioned method of maintaining the liquid film is, for example, the communicating pipe principle, the capillary phenomenon, the hydrophilicity treatment, the waterfall principle, the external applied pressure, or any combination thereof. The method of the hydrophilicity treatment includes forming a groove inside the side surface of the gasification pipe 134 connecting with the electronic component 120.

The aforementioned method of condensing the gasified cooling fluid into liquid in the condenser 160 is, for example, providing a reaction space in the condenser 160 to condense the gas into liquid, or employing at least one heat exchanger.

The aforementioned method of enabling the cooling fluid in the liquid state to flow back to the storage tank 100 from the condenser 160 through the liquid pipe 132 is, for example, through gravity or the capillary force. The method of increasing the capillary force is, for example, forming a micro structure with capillary force in the liquid pipe 132 from the condenser 160 to the storage tank 100, and the method of increasing gravity is, for example, configuring at least one pump in the liquid pipe from the condenser 160 to the storage tank 100.

At least one pump is configured at the liquid pipe 132 used for connecting the storage tank 100 with the condenser 160, or serving as the pipe for the back flows of the storage tank 100 itself, so as to increase the flowing pressure of the cooling flow for a long-range flowing or flowing against gravity.

FIG. 2 is a schematic view of maintaining the liquid film through a communicating pipe principle for the closed-loop latent heat cooling method and the module thereof according to one preferred embodiment of the present invention. As shown in FIG. 2, with the communicating pipe principle, for example, the liquid level of the storage tank 200 is higher than that of the gasification pipe 234, so as to maintain a liquid film in the gasification pipe 234, wherein the thickness of the liquid film can be adjusted by using the height difference between the liquid level of the storage tank 200 and that of the gasification pipe 234.

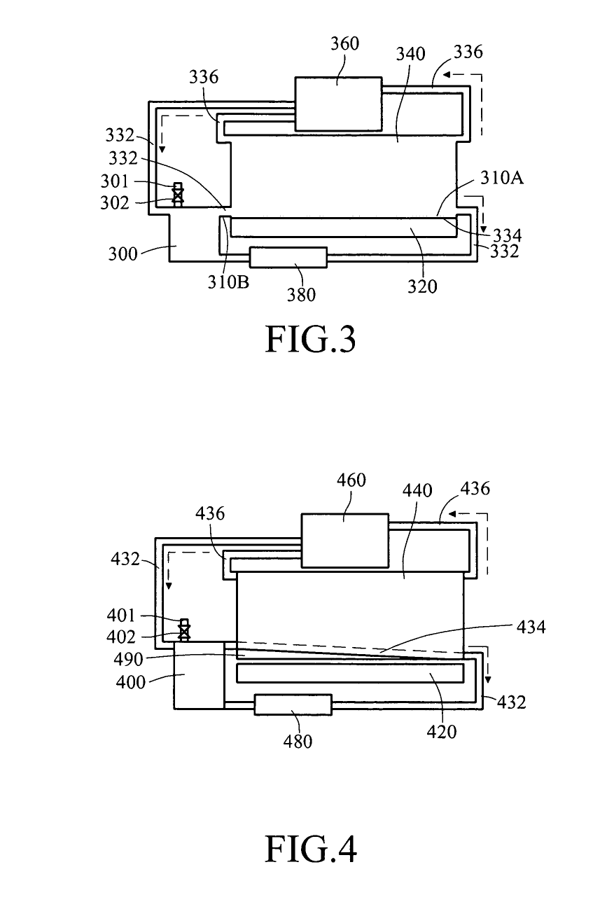

FIG. 3 is a schematic view of maintaining the liquid film through a combination of a capillary phenomenon and the externally applied pressure for the closed-loop latent heat cooling method and the module thereof according to one preferred embodiment of the present invention. As shown in FIG. 3, with the method of the combination of the capillary phenomenon and the externally applied pressure being employed in this embodiment, for example, the micro structure 310A with the capillary force is formed inside the side surface of the gasification pipe 334 connecting with the electronic component 320, wherein the cooling fluid is forced to be within the micro structure 310A with the capillary force, due to the surface tension of the cooling fluid itself and the attracting force of the micro structure with the capillary force. Thus, the microstructure 310A may be used to control the thickness of the liquid film for the cooling fluid. The thickness of the microstructure 310A falls within 2 millimeters to 10 millimeters. Furthermore, a pump 380 is mounted at the liquid pipe 332 for the back flow of the storage tank 300. In addition, the method of utilizing the capillary phenomenon is, for example, forming a micro structure 310B with the capillary force in the liquid pipe 332 from the storage tank 300 to the gasification pipe 334, so as to enhance the ability of pulling the cooling fluid from the storage tank 300 to the gasification pipe 334, thereby facilitating maintenance of the liquid film.

The aforementioned microstructure is, for example, a multi-hole microstructure, a reticulated microstructure, or a sinter-particle microstructure, wherein the material of the microstructure is, for example, a metal, nonmetal, or polymer. The method for manufacturing the microstructure is, for example, precision finishing, micro-electromechanical system, or sintering.

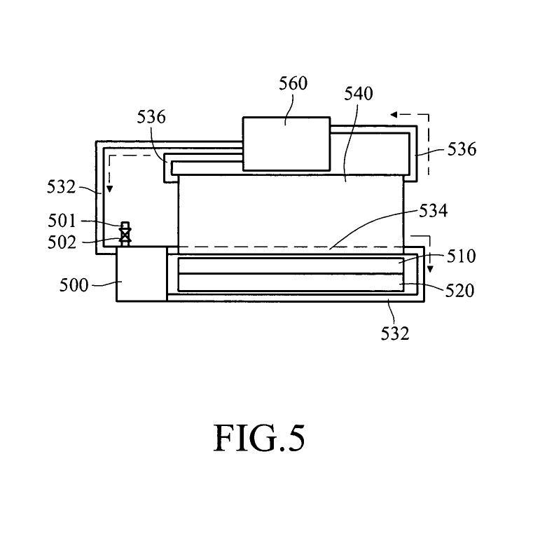

FIG. 4 is a schematic view of maintaining the liquid film through the combination of the waterfall principle and the externally applied pressure for the closed-loop latent heat cooling method and the module thereof according to one preferred embodiment of the present invention. As shown in FIG. 4, with the method of the combination of the waterfall phenomenon and the externally applied pressure being employed in this embodiment, for example, a triangle high heat-conductive material block 490 is configured outside the side surface of the gasification pipe 434 connecting with the electronic component 420, and a pump 480 is disposed at the liquid pipe 432 for the back flow of the storage tank 400. Under the externally applied pressure applied by the pump 480, the amount of the cooling fluid from the storage tank 400 to the gasification pipe 434 is increased. The triangle high heat-conductive material block 490 enables the cooling fluid to form a waterfall phenomenon when entering into the gasification pipe 434 under the pressure effect of the pump 480. Thus, excessive liquid will not accumulate in the gasification pipe 434 to avoid generating excessive-thick liquid film, which is helpful for keeping the liquid film in the film boiling state.

FIG. 5 is a schematic view of using the cooling fluid with a high boiling temperature by employing an external cooling chip for the closed-loop latent heat cooling method and the module thereof according to one preferred embodiment of the present invention. As shown in FIG. 5, a cooling chip 510 is disposed outside the side surface of the gasification pipe 534 connecting with the electronic component 520, so as to use the cooling fluid with high boiling temperature, wherein the cooling fluid with high boiling temperature is, for example, water. In this embodiment, through using the cooling chip 510, the temperature of the electronic component 520 may be reduced more efficiently, and the temperature of the cooling fluid in the gasification pipe 534 may be further increased, such that the cooling fluid is gasified. Therefore, a liquid with a high boiling temperature may be used as the cooling fluid in the present invention. For example, in the current mechanism with water as the cooling fluid, since the chip of the electronic component, such as a CPU, cannot accept the boiling point of water, 100° C., the system generally requires to be vacuumized to reduce the boiling point of water, such that water can be used as the cooling fluid to be gasified and relieve the heat generated by the chip. However, as such, not only are the complexity and cost of the system increased, but the reliability is also reduced. In the embodiment of the present invention, the cooling chip 510 is further installed not only to reduce the temperature of the electronic component 520 efficiently, but also to further increase the temperature of the cooling fluid in the gasification pipe 534, thereby keeping the liquid film in the film boiling state without the vacuumizing process.

In view of the above, in the present invention, the communicating pipe principle, the capillary phenomenon, the hydrophilicity treatment, the waterfall principle, the externally applied pressure, or any combination thereof may be used to suitably control the amount of the cooling fluid, such that the cooling fluid is maintained to be the liquid film in the film boiling state. Therefore, in the case of absorbing with high calorific wattage, the cooling fluid will not be so insufficient that the cooling fluid cannot be gasified and dries up, allowing the electronic component to be burned and damaged.

In the present invention, the liquid film is kept in the film boiling state, so as to achieve the higher heat cooling efficiency, and water can be used as the cooling fluid, which meets environmental protection requirements and reduces the manufacturing cost.

In addition, the principles of the latent heat transfer during the gas-liquid two-phase change and the capillary force are used to rapidly relieve the heat of the electronic component, thereby achieving the object of heat cooling with high efficiency and high wattage.

The structure in the present invention can be applied to the vertical or horizontal electronic component, which is designed in a flexible configuration.

In the present invention, the nozzle and ink jet are not required, so as to avoid the problem that the collision between the gas-liquid two phases of the cooling fluid in a gas area results in the reduction of a heat transfer coefficient, thereby enhancing heat cooling efficiency, and the system is not required to be vacuumized, thereby reducing the complexity and the manufacturing cost of the heating cooling module.

Finally through employing the cooling chip, the heat cooling efficiency of the electronic component is enhanced, and a liquid with a high boiling point can be used as the cooling fluid.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A closed-loop latent heat cooling method, comprising:
providing a storage tank for storing a cooling fluid within the storage tank;
utilizing a first liquid pipe connected with the storage tank to allow the cooling fluid flowing into a gasification pipe through an electronic component;
gasifying the cooling fluid to be a vaporized state to enable the gasified cooling fluid to rise to a vapor chamber;
utilizing a vapor pipe connected between the vapor chamber and a condenser to allow the gasified cooling fluid flowing into the condenser;
condensing the gasified cooling fluid by the condenser; and
utilizing a second liquid pipe connected between the condenser and the storage tank to allow the condensed cooling fluid flowing back to the storage tank.

2. The closed-loop latent heat cooling method as claimed in claim 1, wherein the side surface of the gasification pipe is connected to the vapor chamber by an open connection.

3. The closed-loop latent heat cooling method as claimed in claim 1, wherein the cooling fluid stored in the storage tank has the liquid level higher than the gasification pipe.

4. The closed-loop latent heat cooling method as claimed in claim 1, further comprising:
forming a microstructure with capillary force inside the side surface of the gasification pipe for enabling the gasified cooling fluid to rise to a vapor chamber.

5. The closed-loop latent heat cooling method as claimed in claim 4, further comprising:
providing a pump to the first liquid pipe for allowing the cooling fluid flowing into the gasification pipe.

6. The closed-loop latent heat cooling method as claimed in claim 1, further comprising:
forming a microstructure with capillary force within the first liquid pipe connected between the storage tank with the gasification for enabling the cooling fluid stored in the storage tank flowing to the gasification pipe.

7. The closed-loop latent heat cooling method as claimed in claim 1, further comprising:
configuring a triangle high heat-conductive material block outside the side surface of the gasification pipe connected with the electronic component to form a waterfall.

8. The closed-loop latent heat cooling method as claimed in claim 1, further comprising:
providing a pump to the first liquid pipe for allowing the cooling fluid flowing into the gasification pipe.

9. The closed-loop latent heat cooling method as claimed in claim 1, further comprising:
configuring a cooling chip outside the side surface of the gasification pipe connected with the electronic component.

10. The closed-loop latent heat cooling method as claimed in claim 1, further comprising:
forming a microstructure with capillary force at the second liquid pipe from the condenser to the storage tank for allowing the cooling fluid in a liquid state flowing back to the storage tank from the condenser through the second liquid pipe.

11. The closed-loop latent heat cooling method as claimed in claim 1, further comprising:
providing at least one pump to the second liquid pipe for allowing the cooling fluid in a liquid state flowing back to the storage tank from the condenser through the second liquid pipe.

12. The closed-loop latent heat cooling method as claimed in claim 1, wherein the condenser provides a reaction space for condensing the gasified cooling fluid into the liquid cooling fluid.

13. The closed-loop latent heat cooling method as claimed in claim 1, wherein the condenser further comprises at least one exchanger for condensing the gasified cooling fluid into the liquid cooling fluid.

14. A capillary force closed-loop latent heat cooling module, comprising:
a cooling fluid, for absorbing the heat of an electronic component;
a storage tank, for storing the cooling fluid;
a vapor chamber, which is a region for accommodating the gas generated by the cooling fluid being boiling and vaporized after absorbing the heat of the electronic component;
a condenser, for condensing the gasified cooling fluid into the cooling fluid in a liquid state; and
a loop pipe, for connecting the storage tank, the vapor chamber, and the condenser into a closed loop, and including a liquid pipe, a vapor pipe, and a gasification pipe, wherein the liquid pipe connects the storage tank and the gasification pipe, connects the storage tank and the condenser, and serves as the pipe for the back flow of the storage tank itself; the vapor pipe connects the vapor chamber and the condenser; the gasification pipe connects between the liquid pipes, with two side surfaces being connected with the electronic component and the vapor chamber respectively, and a micro structure with capillary force is disposed in the gasification pipe to form a liquid film kept in a film boiling state.

15. The capillary force closed-loop latent heat cooling module as claimed in claim 14, wherein the microstructure with capillary force is located inside the side surface of the gasification pipe connecting with the electronic component.

16. The capillary force closed-loop latent heat cooling module as claimed in claim 14, wherein the micro structure with capillary force is further located in the liquid pipe from the storage tank to the gasification pipe or from the condenser to the storage tank.

17. The capillary force closed-loop latent heat cooling module as claimed in claim 14, wherein the thickness of the microstructure with capillary force falls within 2 millimeters to 10 millimeters.

18. The capillary force closed-loop latent heat cooling module as claimed in claim 14, wherein the micro structure with capillary force includes a multi-hole microstructure, a reticulated microstructure, or a sinter-particle microstructure.

19. The capillary force closed-loop latent heat cooling module as claimed in claim 14, wherein the material of the microstructure with capillary force includes a metal, a nonmetal, or a polymer.

20. The capillary force closed-loop latent heat cooling module as claimed in claim 14, wherein at least one pump is configured at the liquid pipe.

21. The capillary force closed-loop latent heat cooling module as claimed in claim 14, wherein the material of the gasification pipe includes a high heat-conductive material.

22. The capillary force closed-loop latent heat cooling module as claimed in claim 14, wherein each of the loop pipe, the storage tank, the vapor chamber, and the condenser is formed by integrating or bonding, and they are combined with one another by integrating or bonding.

23. The capillary force closed-loop latent heat cooling module as claimed in claim 22, wherein the bonding method is through sintering or installing at least one fastener.

24. The capillary force closed-loop latent heat cooling module as claimed in claim 14, wherein the condenser provides a reaction space for condensing the gas into liquid or uses at least one heat exchanger.

25. A non-nozzle closed-loop latent heat cooling module, comprising:
a cooling fluid, for absorbing the heat of an electronic component;
a storage tank, for storing the cooling fluid;
a vapor chamber, which is a region for accommodating the gas generated by the cooling fluid being boiling and vaporized after absorbing the heat of the electronic component;
a condenser, for condensing the gasified cooling fluid to be the cooling fluid in a liquid state; and
a loop pipe, for connecting the storage tank, the vapor chamber, and the condenser into a closed loop, and including a liquid pipe, a vapor pipe, and a gasification pipe, wherein the liquid pipe connects the storage tank and the gasification pipe, connects the storage tank and the condenser, and serves as the pipe for the back flow of the storage tank itself; the vapor pipe connects the vapor chamber and the condenser; the gasification pipe connects at the liquid pipes, with two side surfaces connecting the electronic component and the vapor chamber respectively, and a non-nozzle structure is employed in the gasification pipe to form a liquid film kept in the film boiling state.

26. The non-nozzle closed-loop latent heat cooling module as claimed in claim 25, wherein the liquid level of the gasification pipe is lower than that of the storage tank.

27. The non-nozzle closed-loop latent heat cooling module as claimed in claim 25, wherein a cooling chip or a triangle high heat-conductive material block is disposed outside the side surface of the gasification pipe connecting with the electronic component.

28. The non-nozzle closed-loop latent heat cooling module as claimed in claim 25, wherein a hydrophilicity surface treatment is conducted within the side surface of the gasification pipe connecting with the electronic component.

29. The non-nozzle closed-loop latent heat cooling module as claimed in claim 28, wherein the hydrophilicity surface treatment includes forming a groove inside the side surface.

30. The non-nozzle closed-loop latent heat cooling module as claimed in claim 25, wherein at least one pump is configured at the liquid pipe.

31. The non-nozzle closed-loop latent heat cooling module as claimed in claim 25, wherein the material of the gasification pipe includes a high heat-conductive material.

32. The non-nozzle closed-loop latent heat cooling module as claimed in claim 25, wherein each of the loop pipe, the storage tank, the vapor chamber, and the condenser is formed by integrating or bonding, and they are combined with one another by integrating or bonding.

33. The non-nozzle closed-loop latent heat cooling module as claimed in claim 32, wherein the bonding method is sintering or installing at least one fastener.

34. The capillary force closed-loop latent heat cooling module as claimed in claim 25, wherein the condenser provides a reaction space for condensing the gas into liquid or uses at least one heat exchanger.
